(19) United States
(12) Patent Application Publication
(10) Pub. No.: US 2024/0087793 A1
(43) Pub. Date: Mar. 14, 2024

(54) ELECTRONIC COMPONENT AND METHOD FOR MANUFACTURING THE SAME

(71) Applicant: Murata Manufacturing Co., Ltd., Kyoto (JP)

(72) Inventors: Hirofumi OIE, Nagaokakyo-shi (JP); Yoshihito OTSUBO, Nagaokakyo-shi (JP)

(21) Appl. No.: 18/510,766

(22) Filed: Nov. 16, 2023

Related U.S. Application Data
(63) Continuation of application No. PCT/JP2022/004716, filed on Feb. 7, 2022.

(30) Foreign Application Priority Data
May 21, 2021 (JP) 2021-086392

(51) Int. Cl. H01F 27/28; H01F 27/32; H01F 41/04; H01G 4/005; H01G 4/224; H01G 4/33

(52) U.S. Cl. CPC H01F 27/2804; H01F 27/327; H01F 41/043; H01G 4/005; H01G 4/224; H01G 4/33

(57) ABSTRACT

An electronic component includes a plurality of base materials laminated in a thickness direction, interlayer connection conductor provided in base materials and filled in a through hole penetrating in the thickness direction, and internal electrode formed at a position where internal electrode overlaps interlayer connection conductor when viewed from the thickness direction, internal electrode being formed with base material interposed between internal electrode and interlayer connection conductor. Interlayer connection conductor has a cavity. Cavity being formed so as to be shifted internal electrode side in the thickness direction of the through hole.

### CROSS REFERENCE TO RELATED APPLICATION

This is a continuation of International Application No. PCT/JP2022/004716 filed on Feb. 7, 2022 which claims priority from Japanese Patent Application No. 2021-086392 filed on May 21, 2021. The contents of these applications are incorporated herein by reference in their entireties.

### BACKGROUND OF THE DISCLOSURE

### Field of the Disclosure

The present disclosure relates to an electronic component including a plurality of insulating layers laminated in a thickness direction and an interlayer connection conductor filled in a through hole penetrating the insulating layer in the thickness direction, and a method for manufacturing the electronic component.

### Description of the Related Art

Patent Document 1 discloses a high frequency component as an example of an electronic component including an insulating layer, a plurality of insulating layers laminated in a thickness direction, and an interlayer connection conductor filled in a through hole penetrating the insulating layer in the thickness direction. The high frequency component disclosed in Patent Document 1 includes a ceramic substrate in which a plurality of ceramic layers (corresponding to insulating layers) are laminated, a wiring electrode formed inside the ceramic substrate, and an external electrode formed on a lower surface of the ceramic substrate. The wiring electrode and the external electrode are connected via a via conductor (corresponding to an interlayer connection conductor) formed in the ceramic layer.
Patent Document 1: WO 2017/179325 A

### BRIEF SUMMARY OF THE DISCLOSURE

In a manufacturing process for an electronic component, insulating layers in which interlayer connection conductors are formed are laminated on each other. In this lamination process, the interlayer connection conductor and the insulating layer are pressure-bonded or the like to be deformed. Since materials of the interlayer connection conductor and the insulating layer are different, shrinkage rates of the interlayer connection conductor and the insulating layer are different. Therefore, the interlayer connection conductor may protrude from the insulating layer due to the deformation.

The raised interlayer connection conductor may be short-circuited with another conductor separated from the interlayer connection conductor via the insulating layer in a normal state. In a case where the interlayer connection conductors formed in the plurality of insulating layers are continuous in the thickness direction, a protrusion amount of the continuous interlayer connection conductors as a whole increases, and thus a possibility of occurrence of the short circuit increases. Also when the insulating layer is thin in thickness, the possibility of occurrence of the short circuit is increased.

Therefore, a possible benefit of the present disclosure is to solve the above problem, and to provide an electronic component in which protrusion of a conductor penetrating an insulating layer from the insulating layer can be suppressed.

In order to achieve the above possible benefit, the present disclosure is configured as follows. An electronic component according to one aspect of the present disclosure includes: a plurality of insulating layers laminated in a thickness direction; a first conductor provided in at least one of the plurality of insulating layers and filled in a through hole penetrating in the thickness direction; and a second conductor formed at a position where at least a part of the second conductor overlaps the first conductor when viewed from the thickness direction, the second conductor being formed with the at least one insulating layer interposed between the second conductor and the first conductor, wherein the first conductor has a cavity, and wherein the cavity being formed so as to be shifted to either one of a second conductor side in the thickness direction of the through hole and a side opposite to the second conductor.

According to the present disclosure, it is possible to suppress a first conductor penetrating an insulating layer from protruding from the insulating layer.

### BRIEF DESCRIPTION OF THE SEVERAL VIEWS OF THE DRAWINGS

FIG. 1 is a bottom view of an electronic component according to a first embodiment of the present disclosure.

FIG. 2 is a cross-sectional view showing a cross section taken along line A-A in FIG. 1.

FIG. 3 is a cross-sectional view when a through hole is formed in a base material in the method for manufacturing an electronic component according to the first embodiment of the present disclosure.

FIG. 4 is a cross-sectional view when an interlayer connection conductor is formed in the through hole of the base material in FIG. 3.

FIG. 5 is a cross-sectional view when the interlayer connection conductor is formed in the through hole of the base material in FIG. 3.

FIG. 6 is a cross-sectional view when an internal electrode is formed in the base material in FIG. 4.

FIG. 7 is a cross-sectional view when an external electrode is formed in the base material in FIG. 5.

FIG. 8 is a cross-sectional view when a plurality of base materials are laminated to form an element body in the method for manufacturing an electronic component according to the first embodiment of the present disclosure.

FIG. 9 is a cross-sectional view of a position corresponding to the cross section taken along line A-A in FIG. 1 in an electronic component according to a second embodiment of the present disclosure.

FIG. 10 is a cross-sectional view when a through hole is formed in a base material in the method for manufacturing an electronic component according to the second embodiment of the present disclosure.

FIG. 11 is a cross-sectional view when an interlayer connection conductor is formed in the through hole of the base material in FIG. 10.

FIG. 12 is a cross-sectional view when the interlayer connection conductor is formed in the through hole of the base material in FIG. 10.

FIG. 13 is an enlarged view of a part corresponding to a part surrounded by a dashed line in FIG. 2 in an electronic component according to a third embodiment of the present disclosure.

### DETAILED DESCRIPTION OF THE DISCLOSURE

An electronic component according to one aspect of the present disclosure includes: a plurality of insulating layers laminated in a thickness direction; a first conductor provided in at least one of the plurality of insulating layers and filled in a through hole penetrating in the thickness direction; and a second conductor formed at a position where at least a part of the second conductor overlaps the first conductor when viewed from the thickness direction, the second conductor being formed with the at least one insulating layer interposed between the second conductor and the first conductor, wherein the first conductor has a cavity, the cavity being formed so as to be shifted to either one of a second conductor side in the thickness direction of the through hole and a side opposite to the second conductor.

According to this configuration, the first conductor has the cavity. When the first conductor is deformed, this enables the deformation of the first conductor to enter the cavity. Therefore, it is possible to suppress the first conductor from protruding from the insulating layer. As a result, a possibility of occurrence of a short circuit between the first conductor and the second conductor due to protrusion of the first conductor can be reduced.

In the electronic component, the through hole may have a tapered shape that decreases in diameter from one end toward the other end in the thickness direction, and the cavity may be formed so as to be shifted to one end side in the thickness direction of the through hole.

The first conductor can be electrically connected to another first conductor formed in another insulating layer and another conductor such as a pad electrode formed on a main surface of the insulating layer. However, when the first conductor includes the cavity, a contact area between the first conductor and the other conductor is reduced by the cavity. This might cause a connection failure between the first conductor and the other conductor.

According to this configuration, the cavity of the first conductor is formed so as to be shifted to a side where the tapered through hole has a larger diameter. Therefore, the contact area between the first conductor and the other conductor can be increased as compared with a configuration in which the cavity of the first conductor is formed so as to be shifted to a side where the diameter of the tapered through hole becomes smaller. As a result, the possibility of occurrence of such connection failure as described above can be reduced.

In the electronic component, the cavity may be formed in a central part of the first conductor when viewed from the thickness direction.

When the first conductor protrudes from the insulating layer, a protrusion amount of the central part of the first conductor when viewed from the thickness direction is larger than a protrusion amount of an outer edge of the first conductor when viewed from the thickness direction. According to this configuration, the cavity is formed in the central part where the protrusion amount increases. This makes it possible to suppress the first conductor from protruding from the insulating layer.

The electronic component may include two first conductors formed respectively in two insulating layers adjacent to each other, and the two first conductors may at least partially overlap each other and may be electrically connected to each other when viewed from the thickness direction.

According to this configuration, the two first conductors are continuous in the thickness direction. In this case, a protrusion amount of the two first conductors as a whole from the insulating layers is larger than a protrusion amount of the first conductor from the insulating layer in a case where the first conductor is not continuous in the thickness direction. According to this configuration, each of the two first conductors includes the cavity. Therefore, a volume of the cavities of the two first conductors as a whole can be increased. As a result, it is possible to suppress the first conductor from protruding from the insulating layer.

The electronic component may further include a third conductor interposed between the two first conductors to electrically connect the two first conductors.

According to this configuration, the third conductor is interposed between the two first conductors. Therefore, an electrical connection between the two first conductors can be strengthened.

In the electronic component, a plurality of sealed spaces may be formed in the first conductor, and the cavity may form a sealed space having the largest volume among the plurality of sealed spaces.

In the electronic component, the first conductor and the second conductor may constitute at least a part of an inductor.

In a case where the first conductor and the second conductor constitute at least a part of the inductor, when the first conductor protrudes from the insulating layer, the number, orientation, and the like of magnetic fluxes penetrating the inductor change, resulting in causing properties of the inductor to vary. According to this configuration, since the first conductor includes the cavity, it is possible to suppress the first conductor from protruding from the insulating layer. Therefore, variations in the properties of the inductor can be suppressed.

In the electronic component, the first conductor and the second conductor may constitute at least a part of a capacitor.

In a case where the first conductor and the second conductor constitute at least a part of the capacitor, when the first conductor protrudes from the insulating layer, an interval between the first conductor and the second conductor changes, resulting in causing properties of the capacitor to vary. According to this configuration, since the first conductor includes the cavity, it is possible to suppress the first conductor from protruding from the insulating layer. Therefore, variations in the properties of the capacitor can be suppressed.

A method for manufacturing an electronic component according to one aspect of the present disclosure includes: a through hole forming step of forming, in at least one of a plurality of insulating layers, a through hole that penetrates the insulating layer in a thickness direction; a first conductor forming step of forming a first conductor by filling the through hole with a conductive material such that a recess that is recessed in the thickness direction is formed on an end surface on one end side in the thickness direction of the through hole; a second conductor forming step of forming a conductive second conductor in at least one of the plurality of insulating layers; and a laminating step of laminating the plurality of insulating layers in the thickness direction such that at least a part of the first conductor and a part of the second conductor overlap each other when viewed from the thickness direction, and at least one of the insulating layers is interposed between the first conductor and the second conductor.

According to this manufacturing method, in the first conductor forming step, the recess is formed in the first conductor. As a result, in the subsequent laminating step or the like, by an amount of deformation of the first conductor when the first conductor is deformed, an electrode formed in another base material laminated on the first conductor, and the like can be made to enter the recess. This makes it possible to suppress the first conductor from protruding from the insulating layer.

In the manufacturing method, in the laminating step, the plurality of insulating layers may be laminated such that an opening of the recess is covered with at least one of the laminated insulating layer, the first conductor, and the second conductor to hermetically seal a space formed by the recess to form a cavity.

When the recess is eliminated due to the deformation of the recess or the like in the laminating step, the electrode formed in the other base material laminated on the first conductor, and the like cannot enter the recess by an amount of the deformation of the first conductor. This might cause the first conductor to protrude from the insulating layer. According to this manufacturing method, a space formed by the recess is not completely eliminated, and the cavity is formed by the remaining space. This makes it possible to suppress the first conductor from protruding from the insulating layer.

In the manufacturing method, in the through hole formation step, the through hole may be formed so as to have a diameter that decreases from one end toward the other end in the thickness direction.

According to this manufacturing method, a diameter on the one end side in the thickness direction of the through hole is larger than a diameter on the other end side in the thickness direction of the through hole, and the recess of the first conductor is formed on an end surface on the one end side in the thickness direction of the through hole, i.e., an end surface on a side having the larger diameter. This enables the recess formed in the first conductor to be enlarged. As a result, when the first conductor is deformed, by a larger amount of deformation of the first conductor, an electrode formed in the other base material, and the like can be made to enter the recess.

In the manufacturing method, in the through hole formation step, the through hole may be formed in the plurality of insulating layers, in the first conductor forming step, the first conductor may be formed in each of the through holes, and in the laminating step, the plurality of insulating layers may be laminated in the thickness direction such that at least a part of the plurality of first conductors overlap and are electrically connected to each other when viewed from the thickness direction.

According to this manufacturing method, the first conductor can be continuously formed in the thickness direction in the laminating step.

The manufacturing method may further include a third conductor forming step of forming a third conductor on a main surface of at least one of the plurality of insulating layers so as to cover at least a part of the first conductor, and in the laminating step, the plurality of insulating layers may be laminated in the thickness direction such that the third conductor is interposed between two adjacent first conductors to electrically connect the two first conductors.

According to this manufacturing method, in the laminating step, a plurality of insulating layers are laminated such that the third conductor is interposed between the two first conductors. Therefore, an electrical connection between the two first conductors can be strengthened.

### First Embodiment

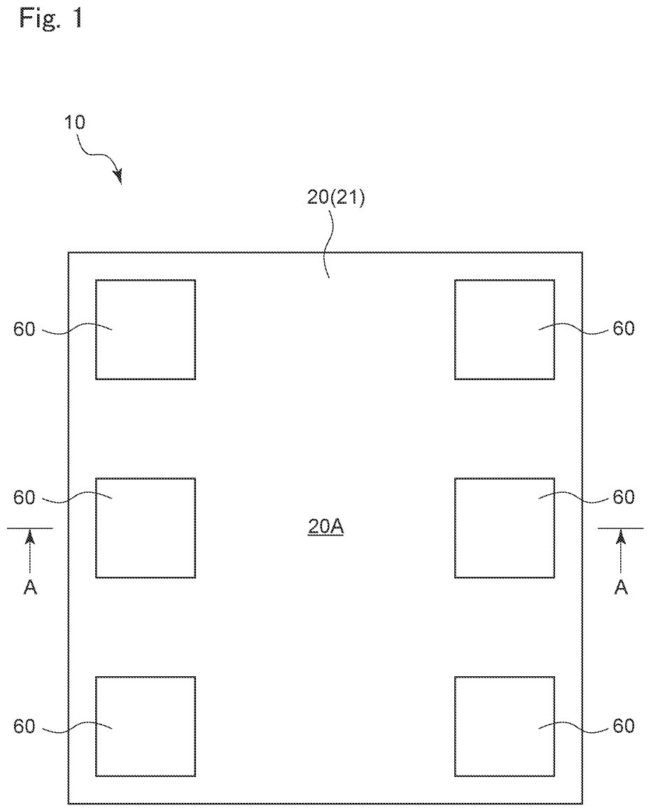

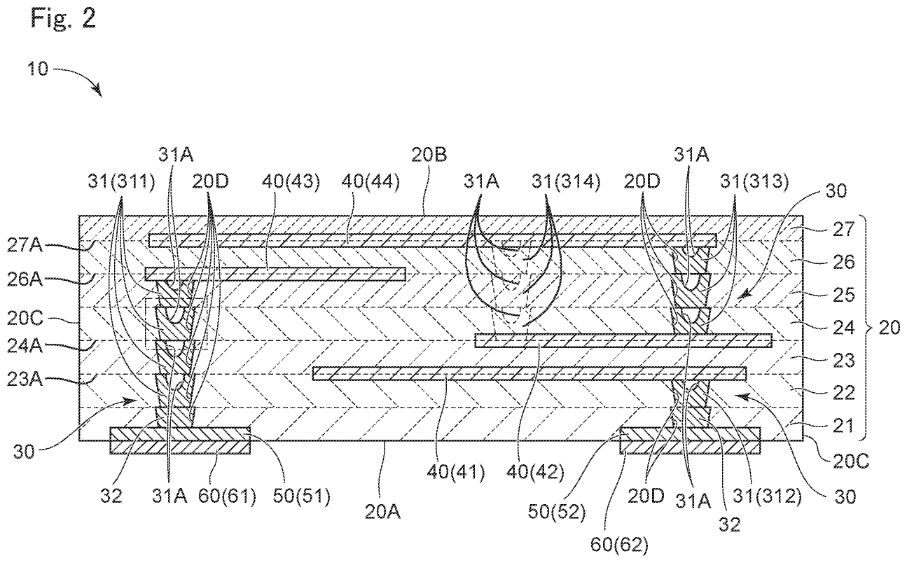

FIG. 1 is a bottom view of an electronic component according to a first embodiment of the present disclosure. FIG. 2 is a cross-sectional view showing a cross section taken along line A-A in FIG. 1. The electronic component includes an element body provided with an interlayer connection conductor, an internal electrode, and an external electrode. The electronic component can be mounted on a mother substrate or the like via the external electrode.

As shown in FIGS. 1 and 2, an electronic component 10 according to the first embodiment includes an element body 20, an interlayer connection conductor 30, an internal electrode 40, an external electrode 50, and a plating layer 60.

The element body 20 has a rectangular parallelepiped shape as a whole. The shape of the element body 20 is not limited to a rectangular parallelepiped shape. In the first embodiment, the element body 20 is formed by integrating seven base materials 21 to 27 laminated in a thickness direction of each of the base materials 21 to 27. The number of layers of the base materials constituting the element body 20 is not limited to seven. Each of the base materials 21 to 27 is insulative and has a plate shape. The base materials 21 to 27 are an example of an insulating layer. In the first embodiment, the element body 20 (each of the base materials 21 to 27) is made of low temperature co-fired ceramics (LTCC). The element body 20 is not limited to LTCC, and may be made of ceramic other than LTCC, such as alumina, or may be made of resin such as glass epoxy, Teflon (registered trademark), or paper phenol.

As illustrated in FIG. 2, the element body 20 includes main surfaces 20A and 20B and a side surface 20C. The main surface 20A is a main surface of the base material 21 and faces the outside of the element body 20. The main surface 20B is a main surface of the base material 27 and faces the outside of the element body 20. The main surface 20B faces opposite to the main surface 20A. The side surface 20C is configured with side surfaces of the base materials 21 to 27. The side surface 20C links the main surfaces 20A and 20B.

The interlayer connection conductor 30 is formed inside the element body 20. The interlayer connection conductor 30 can be formed in at least one of the base materials 21 to 27. In the first embodiment, the interlayer connection conductor 30 is formed in the base materials 21 to 26.

The interlayer connection conductor 30 is formed by filling a through hole 20D penetrating at least one layer of the plurality of base materials 21 to 27 in the thickness direction of the base materials 21 to 27 with a conductive paste and co-firing the paste with ceramic (LTCC in the first embodiment). The conductive paste contains, for example, a conductive powder such as copper. The conductive powder contained in the conductive paste is not limited to copper, and may be, for example, silver. In a case where the element body 20 is made of resin, the interlayer connection conductor 30 is formed by plating conductive metal made of copper, silver, or the like.

In the first embodiment, the through hole 20D has a diameter that decreases from the main surface 20B toward the main surface 20A along the thickness direction. Specifically, the through hole 20D has a tapered shape having a diameter that decreases from one end (an end on the main surface 20B side) toward the other end (an end on the main surface 20A side) in the thickness direction. Therefore, in the first embodiment, the interlayer connection conductor 30 has a truncated cone shape. Note that in the through hole 20D, a positional relationship between a part having a small diameter and a part having a diameter larger than the small diameter may be converse to that of FIG. 2. In other words, in FIG. 2, although the through hole 20D has a diameter that decreases toward a lower side of a page, contrary thereto, the through hole 20D may be configured to have a diameter that decreases toward an upper side of the page. Such a configuration can be realized, for example, by reversing a lamination order of the base materials 21 to 27.

In the first embodiment, as illustrated in FIG. 2, the interlayer connection conductor 30 includes eight interlayer connection conductors 31 and two interlayer connection conductors 32. The interlayer connection conductor 31 is an example of a first conductor. Two interlayer connection conductors 31 are provided in each of the base materials 22, 24, and 25, and one interlayer connection conductor 31 is provided in each of the base materials 23 and 26. The two interlayer connection conductors 32 are provided in the base material 21. The number of the interlayer connection conductors 31 and 32 is not limited to the number described above.

The eight interlayer connection conductors 31 include four continuous interlayer connection conductors 311, one interlayer connection conductor 312, and three continuous interlayer connection conductors 313. In FIG. 2, four interlayer connection conductors 311 and one interlayer connection conductor 32 are formed to be aligned in the thickness direction. In addition, one interlayer connection conductor 312 and one interlayer connection conductor 32 are formed to be aligned in the thickness direction. In addition, three interlayer connection conductors 313 are formed to be aligned in the thickness direction. In other words, as illustrated in FIG. 2, the electronic component 10 includes two interlayer connection conductors 30 formed in two adjacent base materials, respectively. Among the interlayer connection conductors 30 formed to be aligned in the thickness direction, two adjacent interlayer connection conductors 30 overlap at least partially and are electrically connected to each other when viewed from the thickness direction.

In the first embodiment, a length in the thickness direction of the five continuous interlayer connection conductors 31 and 32 including the four interlayer connection conductors 311 and one interlayer connection conductor 32 is longer than a thickness of the base material 26. A length in the thickness direction of the two continuous interlayer connection conductors 31 and 32 including one interlayer connection conductor 312 and one interlayer connection conductor 32 is longer than a thickness of the base material 23. A length in the thickness direction of the three continuous interlayer connection conductors 313 is longer than the thickness of the base material 23.

The interlayer connection conductor 31 has a cavity 31A. On the other hand, the interlayer connection conductor 32 does not have the cavity 31A. The cavity 31A forms a sealed space.

In the first embodiment, a part of the cavity 31A is defined by the interlayer connection conductor 31 in which the cavity 31A is formed. The remaining part of the cavity 31A is defined by the interlayer connection conductor 31 or the internal electrode 40 adjacent to the interlayer connection conductor 31 in which the cavity 31A is formed.

Note that the remaining part of the cavity 31A may be defined by, for example, the external electrode 50 other than the above described adjacent interlayer connection conductor 31 and internal electrode 40. Furthermore, the entire cavity 31A may be defined by the interlayer connection conductor 31 in which the cavity 31A is formed.

In the first embodiment, the cavity 31A of each interlayer connection conductor 31 is formed so as to be shifted to the main surface 20B side in the thickness direction. In other words, the cavity 31A of each interlayer connection conductor 31 is formed so as to be shifted to the one end side in the thickness direction of the through hole 20D (the side where the through hole 20D has a large diameter). Note that the cavity 31A of each interlayer connection conductor 31 may be formed so as to be shifted to the main surface 20A side in the thickness direction.

When viewed from the thickness direction, the cavity 31A of each interlayer connection conductor 31 is formed in a central part of the interlayer connection conductor 31.

As illustrated in FIG. 2, the internal electrode 40 is formed inside the element body 20 and is not exposed to the outside of the element body 20. The internal electrode 40 can be formed in at least one of the base materials 21 to 27.

In a case where the element body 20 is made of ceramic as in the first embodiment, the internal electrode 40 is formed by printing a conductive paste on the main surface (in the first embodiment, the main surfaces 23A, 24A, 26A, and 27A) of the base material and co-firing the paste with the base material. The conductive paste is made of, for example, copper or silver. In a case where the element body 20 is made of resin, the internal electrode 40 is formed on the main surface of the base material by a known means such as metal foil etching.

In the first embodiment, the electronic component 10 includes four internal electrodes 40 (internal electrodes 41, 42, 43, and 44).

The internal electrode 41 is formed on the main surface 23A of the base material 23. The internal electrode 41 is in contact with the interlayer connection conductor 312 and is electrically connected to the interlayer connection conductor 312. When viewed from the thickness direction, a part of the internal electrode 41 overlaps the interlayer connection conductor 313 formed in the base material 24.

The internal electrode 42 is formed on the main surface 24A of the base material 24. The internal electrode 42 is in contact with the interlayer connection conductor 313 formed in the base material 24 and is electrically connected to the interlayer connection conductor 313. When viewed from the thickness direction, a part of the internal electrode 42 overlaps the interlayer connection conductor 312.

The internal electrode 43 is formed on the main surface 26A of the base material 26. The internal electrode 43 is in contact with the interlayer connection conductor 311 formed in the base material 25 and is electrically connected to the interlayer connection conductor 311.

The internal electrode 44 is formed on the main surface 27A of the base material 27. The internal electrode 44 is in contact with the interlayer connection conductor 313 formed in the base material 26 and is electrically connected to the interlayer connection conductor 313. When viewed from the thickness direction, a part of the internal electrode 44 overlaps the interlayer connection conductor 311 formed in the base material 25.

Size, shape, and position of each of the internal electrodes 40 (the internal electrodes 41 to 44) are not limited to the size, the shape, and the position illustrated in FIG. 2. For example, when viewed from the thickness direction, the entire internal electrode 41 may overlap the interlayer connection conductor 313 formed in the base material 24. In this case, the internal electrode 41 is smaller than the size shown in FIG. 2. The same applies to the internal electrodes 42 and 44.

The internal electrode 41 is formed at a position opposed to the interlayer connection conductor 313 with the base material 23 interposed therebetween. The internal electrode 41 may be formed at a position opposed to the interlayer connection conductor 313 with a plurality of base materials interposed therebetween. The internal electrode 41 corresponds to a second conductor when the interlayer connection conductor 313 corresponds to the first conductor.

The internal electrode 42 is formed at a position opposed to the interlayer connection conductor 312 with the base material 23 interposed therebetween. The internal electrode 42 may be formed at a position opposed to the interlayer connection conductor 312 with a plurality of base materials interposed therebetween. The internal electrode 42 corresponds to the second conductor when the interlayer connection conductor 312 corresponds to the first conductor.

The internal electrode 44 is formed at a position opposed to the interlayer connection conductor 311 with the base material 26 interposed therebetween. The internal electrode 44 may be formed at a position opposed to the interlayer connection conductor 311 with a plurality of base materials interposed therebetween. The internal electrode 44 corresponds to the second conductor when the interlayer connection conductor 311 corresponds to the first conductor.

As described in the foregoing, the internal electrode 40 is formed at a position where at least a part of the internal electrode overlaps the interlayer connection conductor 31 when viewed from the thickness direction, with at least one layer of the base material interposed between the internal electrode and the interlayer connection conductor 31.

In the first embodiment, the interlayer connection conductor 31 and the internal electrode 40 formed with at least one layer of the base material interposed therebetween have different potentials. For example, the interlayer connection conductor 311 formed in the base material 25 and the internal electrode 44, the interlayer connection conductor 312 formed in the base material 22 and the internal electrode 42, and the interlayer connection conductor 313 formed in the base material 24 and the internal electrode 41 have different potentials. As a matter of course, the interlayer connection conductor 31 and the internal electrode 40 may have the same potential.

The cavity 31A of the interlayer connection conductor 311 is formed so as to be shifted to the internal electrode 44 (corresponding to the second conductor when the interlayer connection conductor 311 corresponds to the first conductor) side in the thickness direction of the through hole 20D. The cavity 31A of the interlayer connection conductor 312 is formed so as to be shifted to the internal electrode 42 (corresponding to the second conductor when the interlayer connection conductor 312 corresponds to the first conductor) side in the thickness direction of the through hole 20D. Contrary to the above, the cavity 31A of the interlayer connection conductor 313 is formed so as to be shifted at a side opposite to the internal electrode 41 (corresponding to the second conductor when the interlayer connection conductor 313 corresponds to the first conductor) in the thickness direction of the through hole 20D.

As described in the foregoing, the cavity 31A of the interlayer connection conductor 31 is formed so as to be shifted to either one of the second conductor side and the side opposite to the second conductor in the thickness direction of the through hole 20D.

The internal electrodes 43 and 44 are opposed to each other in the thickness direction with the base material 26 interposed therebetween. As a result, the internal electrodes 43 and 44 constitute a capacitor with the base material 26 interposed therebetween. Here, the interlayer connection conductor 311 is electrically connected to a part of the internal electrode 43. Thus, the interlayer connection conductor 311 and the internal electrode 44 constitute a part of the capacitor described above.

When the electronic component 10 does not include the internal electrode 43, the interlayer connection conductor 311 and the internal electrode 44 constitute the entire capacitor with the base material 26 interposed therebetween.

The internal electrodes 41 and 42 are opposed to each other in the thickness direction with the base material 23 interposed therebetween. As a result, the internal electrodes 41 and 42 constitute a capacitor with the base material 23 interposed therebetween. Here, the interlayer connection conductor 312 is electrically connected to a part of the internal electrode 41. Thus, the interlayer connection conductor 312 and the internal electrode 42 constitute a part of the capacitor described above. Similarly, the interlayer connection conductor 313 is electrically connected to a part of the internal electrode 42. Thus, the interlayer connection conductor 313 and the internal electrode 41 constitute a part of the capacitor described above.

In a case where the electronic component 10 does not include the internal electrode 41, the interlayer connection conductor 312 and the internal electrode 42 constitute the entire capacitor with the base material 23 interposed therebetween. Similarly, in a case where the electronic component 10 does not include the internal electrode 42, the interlayer connection conductor 313 and the internal electrode 41 constitute the entire capacitor with the base material 23 interposed therebetween.

As described in the foregoing, the interlayer connection conductor 31 and the internal electrode 40 constitute at least a part of the capacitor.

The interlayer connection conductor 31 and the internal electrode 40 may constitute at least a part of an inductor. For example, as indicated by a broken line in FIG. 2, when three interlayer connection conductors 314 electrically connected to each other are formed in the base materials 24, 25, and 26, respectively, a closed loop is formed by the interlayer connection conductors 313 and 314 and the internal electrodes 42 and 44. This closed loop functions as a coil. In other words, in this case, the interlayer connection conductors 313 and 314 and the internal electrodes 42 and 44 constitute the entire inductor. The inductor constituted by the interlayer connection conductor 31 and the internal electrode 40 is not limited to such closed loop coil as described above. For example, the inductor may be a spiral coil extending in a depth direction of the page of FIG. 2, and the interlayer connection conductor 31 and the internal electrode 40 may constitute a part or the entire of the spiral coil.

The external electrode 50 is formed on an outer part of the element body 20. In the first embodiment, the external electrode 50 is formed on the main surface of the base material 21, i.e., the main surface 20A of the element body 20. The external electrode 50 may be formed on a main surface of the base material 28, i.e., the main surface 20B of the element body 20.

The external electrode 50 is configured in the same manner as the internal electrode 40. Specifically, in the first embodiment, the external electrode 50 is obtained by printing a conductive paste on the main surface 20A of the element body 20 and co-firing the paste with the base materials 21 to 27.

In FIG. 2, the external electrode 50 includes two external electrodes 51 and 52. In the first embodiment, the external electrode 51 is in contact with the interlayer connection conductor 32 adjacent to the interlayer connection conductor 311 and is electrically connected to the interlayer connection conductor 32. The external electrode 52 is in contact with the interlayer connection conductor 32 adjacent to the interlayer connection conductor 312 and is electrically connected to the interlayer connection conductor 32.

The plating layer 60 covers the external electrode 50. The plating layer 60 suppresses influences of atmosphere, moisture, and the like on the external electrodes 51 and 52. The plating layer 60 is a film made of, for example, Ni—Sn, Ni-electroless Au, or the like.

In the first embodiment, as shown in FIG. 1, the electronic component 10 includes six plating layers 60. The number of the plating layers 60 included in the electronic component 10 is not limited to six. In FIG. 2, out of the six plating layers 60, two plating layers 61 and 62 are illustrated. The plating layer 61 covers the external electrode 51. The plating layer 62 covers the external electrode 52.

According to the first embodiment, the interlayer connection conductor 31 has the cavity 31A. This enables deformation of the interlayer connection conductor 31 to enter the cavity 31A when the interlayer connection conductor 31 is deformed. Therefore, it is possible to suppress the interlayer connection conductor 31 from protruding from the base material 22 to 26. As a result, it is possible to reduce a possibility of occurrence of a short circuit between the interlayer connection conductor 31 and the internal electrode 41, 42, 44 due to the protrusion of the interlayer connection conductor 31.

The interlayer connection conductor 31 can be electrically connected to another interlayer connection conductor 31 formed in another base material and to another conductor such as a pad electrode formed on the main surface of the base material. However, in a case where the interlayer connection conductor 31 includes the cavity 31A, a contact area between the interlayer connection conductor 31 and the other conductor is reduced by an amount of the cavity 31A. This might cause a connection failure between the interlayer connection conductor 31 and the other conductor.

According to the first embodiment, the cavity 31A of the interlayer connection conductor 31 is formed so as to be shifted to the side where the diameter of the tapered through hole 20D becomes larger. Therefore, the contact area between the interlayer connection conductor 31 and the other conductor can be increased as compared with a configuration in which the cavity 31A of the interlayer connection conductor 31 is formed so as to be shifted to the side where the diameter of the tapered through hole 20D becomes smaller. As a result, the possibility of occurrence of such connection failure as described above can be reduced.

When the interlayer connection conductor 31 protrudes from the base material 22 to 26, a protrusion amount of the central part of the interlayer connection conductor 31 when viewed from the thickness direction is larger than a protrusion amount of an outer edge of the interlayer connection conductor 31 when viewed from the thickness direction. According to the first embodiment, the cavity 31A is formed in the central part where the protrusion amount increases. This makes it possible to suppress protrusion of the interlayer connection conductor 31 from the base material 22 to 26.

According to the first embodiment, the two interlayer connection conductors 31 are continuous in the thickness direction. In this case, a protrusion amount of the two interlayer connection conductors 31 from the base materials as a whole is larger than a protrusion amount of the interlayer connection conductor 31 from the base material in a case where the interlayer connection conductor 31 is not continuous in the thickness direction. According to the first embodiment, each of the two interlayer connection conductors 31 includes the cavity 31A. Therefore, a volume of the cavity 31A of the two interlayer connection conductors 31 as a whole can be increased. As a result, it is possible to suppress the interlayer connection conductor 31 from protruding from the base material.

In a case where the interlayer connection conductor 31 and the internal electrodes 41, 42, and 44 constitute at least a part of the inductor, when the interlayer connection conductor 31 protrudes from the base material, the number, orientation, and the like of magnetic fluxes penetrating the inductor change, resulting in causing properties of the inductor to vary. According to the first embodiment, since the interlayer connection conductor 31 includes the cavity 31A, it is possible to suppress the protrusion of the interlayer connection conductor 31 from the base material. Therefore, variations in the properties of the inductor can be suppressed.

In a case where the interlayer connection conductor 31 and the internal electrodes 41, 42, and 44 constitute at least a part of the capacitor, when the interlayer connection conductor 31 protrudes from the base material, an interval between the interlayer connection conductor 31 and the internal electrode 41, 42, 44 changes, so that the properties of the capacitor vary. According to the first embodiment, since the interlayer connection conductor 31 includes the cavity 31A, it is possible to suppress the protrusion of the interlayer connection conductor 31 from the base material. Therefore, variations in the properties of the capacitor can be suppressed.

Although in the first embodiment, the cavity 31A is formed so as to be shifted to the main surface 20B side in the thickness direction, the cavity may be formed so as to be shifted to the main surface 20A in the thickness direction. In other words, the cavity 31A of each interlayer connection conductor 31 is formed so as to be shifted to the other end side in the thickness direction of the through hole 20D (the side where the through hole 20D has a small diameter).

In the first embodiment, all the cavities 31A are formed so as to be shifted to the main surface 20B side in the thickness direction. However, a part of the cavities 31A may be formed so as to be shifted to the main surface 20B side in the thickness direction, and a part other than the part of the cavity 31A of each interlayer connection conductor 31 may be formed so as to be shifted to the main surface 20A side in the thickness direction.

Although in the first embodiment, the cavity 31A is formed in the central part of the interlayer connection conductor 31 when viewed from the thickness direction, the cavity may be formed in a part other than the central part of the interlayer connection conductor 31, for example, at the outer edge of the interlayer connection conductor 31.

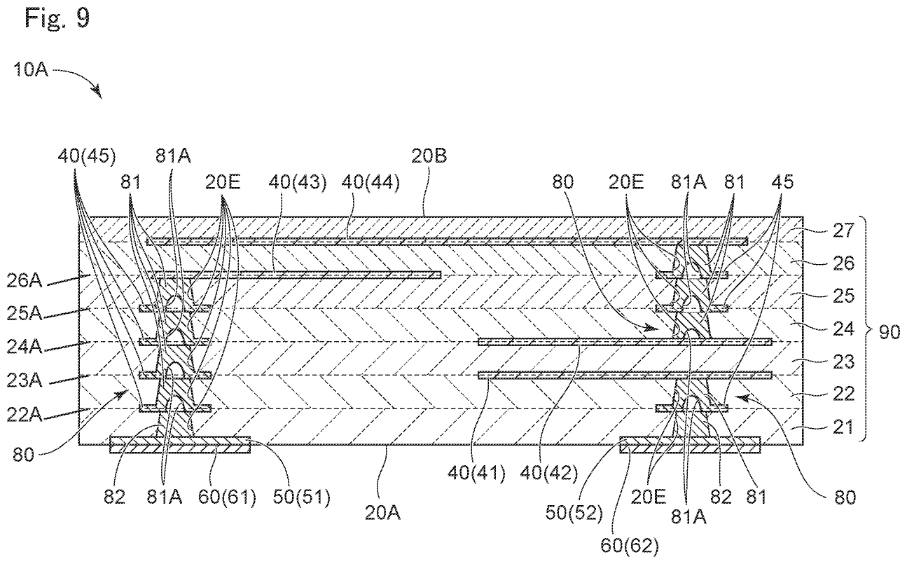

As in an electronic component 10A (see FIG. 9) according to a second embodiment to be described later, the through hole 20D may have a diameter that decreases from the main surface 20A toward the main surface 20B along the thickness direction. In this case, the interlayer connection conductor 30 has a truncated cone shape in a direction opposite to the above. In addition, the through hole 20D is not limited to a tapered shape. For example, the through holes 20D may have the same diameter regardless of a position in the thickness direction. In this case, the interlayer connection conductor 30 has a cylindrical shape. A shape of the interlayer connection conductor 30 is not limited to the cylindrical shape, and may be, for example, a shape such as a quadrangular prism.

<Method for Manufacturing Electronic Component According to First Embodiment>

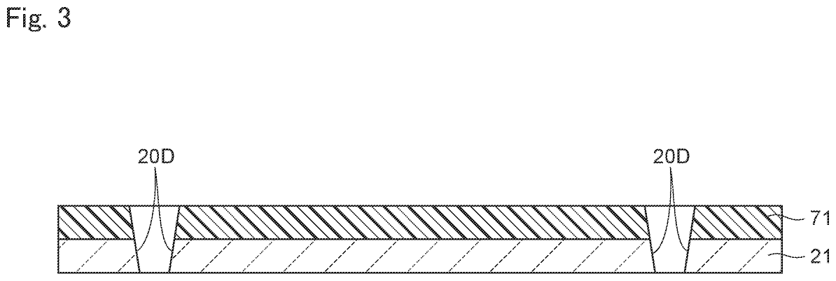

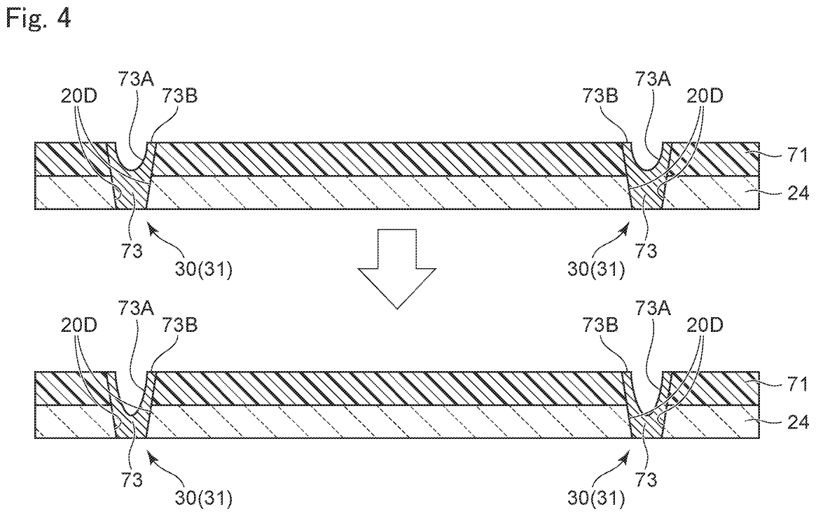

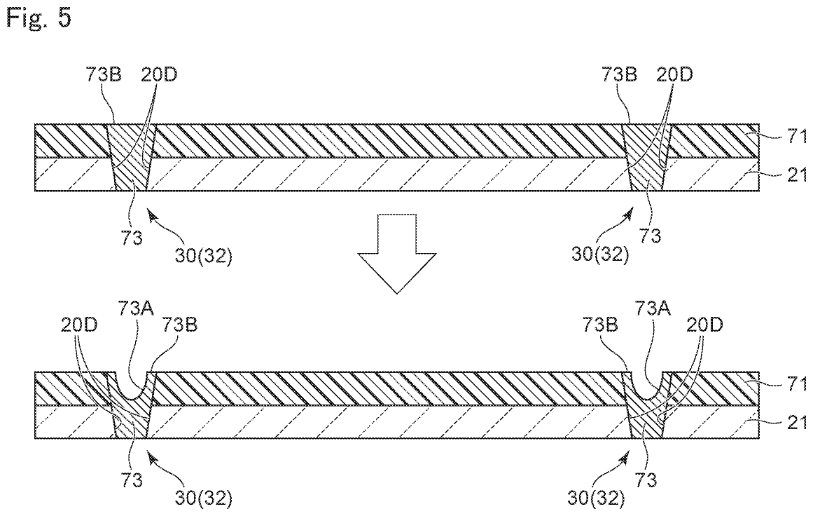

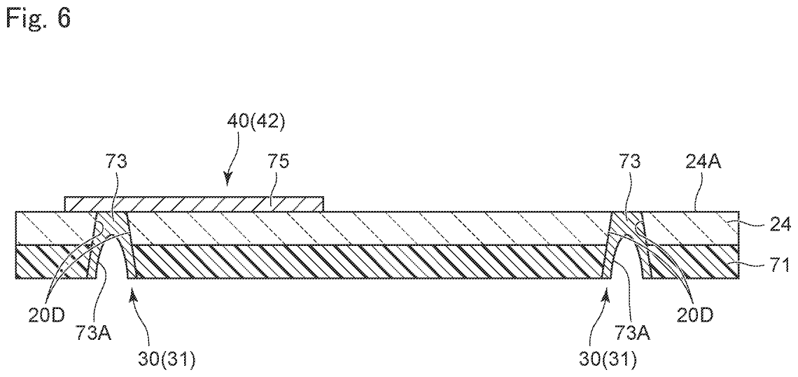

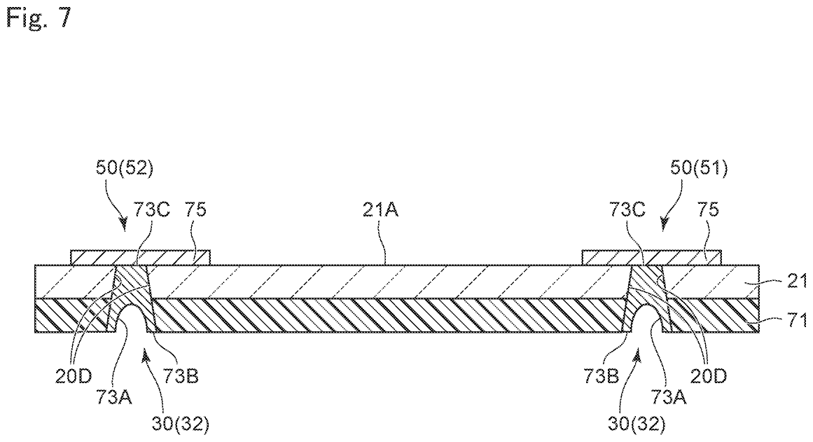

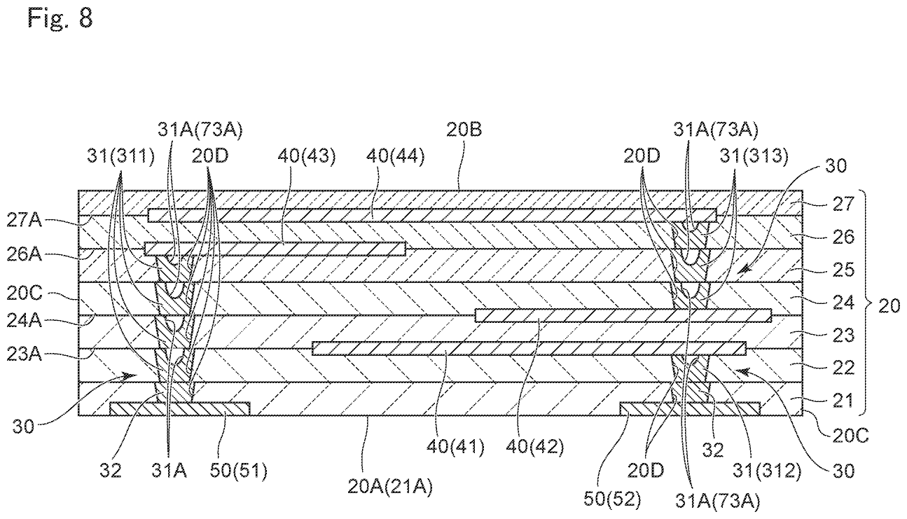

In the following, the method for manufacturing the electronic component 10 according to the first embodiment will be described with reference to FIGS. 3 to 8. FIG. 3 is a cross-sectional view when the through hole is formed in the base material in the method for manufacturing an electronic component according to the first embodiment of the present disclosure. FIG. 4 is a cross-sectional view when the interlayer connection conductor is formed in the through hole of the base material in FIG. 3. FIG. 5 is a cross-sectional view when the interlayer connection conductor is formed in the through hole of the base material in FIG. 3. FIG. 6 is a cross-sectional view when the internal electrode is formed in the base material in FIG. 4. FIG. 7 is a cross-sectional view when the external electrode is formed in the base material in FIG. 5. FIG. 8 is a cross-sectional view when the plurality of base materials are laminated to form the element body in the method for manufacturing an electronic component according to the first embodiment of the present disclosure.

The electronic component 10 is manufactured by segmenting a laminate into a plurality of the element bodies 20. The laminate is formed by integrating the plurality of element bodies 20 in an arrayed state. In FIGS. 3 to 8, for convenience of description, only a part corresponding to one element body 20 of the laminate is shown.

(Sheet Molding Step)

First, a sheet molding step is performed. In the sheet molding step, the base materials 21 to 27 illustrated in FIG. 2 are individually molded. In the base materials 21 to 27 molded in the sheet molding step, a raw material containing a main agent, a plasticizer, a binder, and the like corresponding to each of the base materials 21 to 27 is mainly mixed to prepare slurry constituting each of the base materials 21 to 27. Each of the base materials 21 to 27 at this stage is a green sheet configured with the slurry.

For each of the base materials 21 to 27, for example, a sinterable ceramic powder or the like is used as a main agent. As a plasticizer, for example, phthalic acid ester or di-n-butyl phthalate is used. As a binder, for example, an acrylic resin, polyvinyl butyral, or the like is used.

The slurry constituting each of the base materials 21 to 27 is molded into a sheet shape on the carrier film 71 as illustrated in FIG. 3 using, for example, a lip coater, a doctor blade, or the like. In other words, each of the seven base materials 21 to 27 is molded on each of seven carrier films 71. As the carrier film 71, for example, a polyethylene terephthalate (PET) film or the like is used. Each of the base materials 21 to 27 has a thickness of, for example, 5 to 100 μm.

In FIG. 3, the carrier film 71 and the base material 21 molded on the carrier film 71 are shown.

(Through Hole Forming Step)

Next, a through hole forming step is performed. In the through hole forming step, as illustrated in FIG. 3, the through hole 20D penetrating through each of the base materials 21 to 27 and the carrier film 71 corresponding to each of the base materials 21 to 27 in the thickness direction is formed. The through hole 20D is formed in at least one layer of the base materials 21 to 27.

In the through hole forming step of the method for manufacturing the electronic component 10 according to the first embodiment, the through hole 20D is formed so as to have a diameter that decreases from one end toward the other end in the thickness direction. In the through hole forming step of the method for manufacturing the electronic component 10 according to the first embodiment, the one end in the thickness direction of the through hole 20D is an end on the carrier film 71 side, and the other end in the thickness direction of the through hole 20D is an end on the base materials 21 to 27 side. A shape of the through hole 20D is not limited to the tapered shape as illustrated in FIG. 3.

Although in FIG. 3, two through holes 20D are formed in the base material 21 and the carrier film 71, the number of the through holes 20D formed in each of the base materials 21 to 27 is not limited to two. In addition, the number of the through holes 20D formed in each of the base materials 21 to 27 may be the same or different. In addition, a position of the through hole 20D formed in each of the base materials 21 to 27 may be the same or different.

In the method for manufacturing the electronic component 10 according to the first embodiment, the number and position of the through holes 20D formed in the base materials 21 to 27 are determined so that the element body 20 as shown in FIG. 2 is finally formed. Specifically, in the method for manufacturing the electronic component 10 according to the first embodiment, two through holes 20D are formed in each of the base materials 21, 22, 24, and 25, and one through hole 20D is formed in each of the base materials 23 and 26.

(Interlayer Connection Conductor Forming Step)

Next, an interlayer connection conductor forming step is performed. The interlayer connection conductor forming step corresponds to a first conductor forming step. In the interlayer connection conductor forming step, as illustrated in FIGS. 4 and 5, a conductive paste 73 is filled in each of the through holes 20D formed in each of the base materials 21 to 27 and the carrier films 71 in the through hole forming step. The paste 73 is filled into the through hole 20D from the carrier film 71 side. The filling is performed, for example, by applying the paste 73 to a surface of the carrier film 71 and wiping off the applied paste 73.

The paste 73 is prepared, for example, by mixing a raw material containing a conductive powder, a plasticizer, and a binder. The paste 73 is an example of a conductive material.

In the interlayer connection conductor forming step, a recess 73A is formed in the paste 73 filled in a part of the through holes 20D, and the recess 73A is not formed in the paste 73 filled in the through holes 20D other than the filled part of the through holes 20D. In the method for manufacturing the electronic component 10 according to the first embodiment, the recess 73A is formed in the paste 73 filling the through hole 20D of the base material 22 to 26, and the recess 73A is not formed in the paste 73 filling the through hole 20D of the base material 21. The interlayer connection conductor 31 is formed by the paste 73 in which the recess 73A is formed. The interlayer connection conductor 32 is formed by the paste 73 in which the recess 73A is not formed.

The recess 73A is formed on an end surface 73B on one end side (the carrier film 71 side) in the thickness direction of the through hole 20D. The end surface 73B is a surface on a side of a filling inlet for the paste 73 when the paste 73 is filled in the through hole 20D.

By appropriately setting filling conditions of the paste 73, a depth of the recess 73A of the paste 73 filled in the through hole 20D can be adjusted. The filling conditions are, for example, drying conditions and a composition of the paste 73.

The drying conditions are a drying temperature, a drying time, and the like when the paste 73 filled in the through hole 20D is dried. The higher the drying temperature is, the more the paste 73 to be dried shrinks, so that the recess 73A is liable to be formed deeper. Similarly, the longer the drying time is, the deeper the recess 73A is liable to be formed.

The composition of the paste 73 is, for example, a particle size of the conductive powder (e.g, copper powder) contained in the paste 73. When the paste 73 filled in the through hole 20D is dried, the smaller the particle size of the conductive powder is, the larger an amount of loss of the powder is, so that the recess 73A is liable to be formed deep.

In addition, the composition of the paste 73 is, for example, a percentage of the conductive powder contained in the paste 73. Although the paste 73 contains the conductive powder and a solvent, when a proportion of the solvent is large, holes are liable to be formed in the paste 73, so that the recess 73A is liable to be formed deep.

In addition, for example, as the number of times of filling of the paste 73 (e.g, in a case of screen printing of the paste 73, the number of times of printing) is increased, the recess 73A is less liable to be formed.

When the paste 73 is filled in the through hole 20D of the base material 22 to 26, the recess 73A is formed as illustrated in an upper part of FIG. 4 by adjusting the above-described drying conditions and composition of the paste, and the like. In FIG. 4, the base material 24 is illustrated as a representative of the base materials 22 to 26. Thereafter, when the filled paste 73 is dried, the paste 73 shrinks to make the recess 73A be deeper as illustrated in a lower part of FIG. 4. At this time, the recess 73A reaches a part of the through hole 20D formed in the base materials 22 to 26 from a part of the through hole 20D formed in the carrier film 71.

When the paste 73 is filled in the through hole 20D of the base material 21, the above-described drying conditions and composition of the paste, and the like are adjusted, so that the recess 73A is not formed or is only slightly formed as illustrated in an upper part of FIG. 5. Thereafter, when the filled paste 73 is dried, the paste 73 shrinks to form the recess 73A as illustrated in a lower part of FIG. 5. At this time, the recess 73A remains at a part of the through hole 20D formed in the carrier film 71 and does not reach a part of the through hole 20D formed in the base material 21.

(Internal Electrode Forming Step)

Next, an internal electrode forming step is performed. The internal electrode forming step corresponds to a second conductor forming step. In the internal electrode forming step, the internal electrode 40 is formed in at least one layer of the base materials 21 to 27.

In the method for manufacturing the electronic component 10 according to the first embodiment, as shown in FIG. 6, a paste 75 is formed on the main surface 24A of the base material 24. The paste 75 is formed by, for example, screen printing, inkjet printing, gravure printing, or the like.

Similarly to the paste 73 described above, the paste 75 is prepared by mixing a raw material containing a conductive powder, a plasticizer, and a binder. Note that the paste 75 may be made of the same raw material as that of the paste 73 or may be made of a raw material different from that of the paste 73, provided that the paste 75 contains a conductive raw material.

In the method for manufacturing the electronic component 10 according to the first embodiment, the paste 75 is formed on the main surfaces 23A, 24A, 26A, and 27A of the base materials 23, 24, 26, and 27, respectively.

In the method for manufacturing the electronic component 10 according to the first embodiment, the paste 75 formed on the main surface 24A of the base material 24 corresponds to the internal electrode 42 among the internal electrodes 40 (see FIG. 6). The paste 75 formed on the main surface 23A of the base material 23 corresponds to the internal electrode 41 among the internal electrodes 40. The paste 75 formed on the main surface 26A of the base material 26 corresponds to the internal electrode 43 among the internal electrodes 40. The paste 75 formed on the main surface 27A of the base material 27 corresponds to the internal electrode 44 among the internal electrodes 40.

(External Electrode Forming Step)

Next, an external electrode forming step is performed. The external electrode forming step may be performed after the interlayer connection conductor forming step and before the internal electrode forming step, or may be performed in parallel with the internal electrode forming step.

In the external electrode forming step, the external electrode 50 is formed in the same manner as in the formation of the internal electrode 40 in the internal electrode forming step.

In the method for manufacturing the electronic component 10 according to the first embodiment, as shown in FIG. 7, the paste 75 is formed on a main surface 21A of the base material 21. A part of the paste 75 covers an end surface 73C of the interlayer connection conductor 32 exposed on the main surface 21A, and is electrically connected to the interlayer connection conductor 32.

In the method for manufacturing the electronic component 10 according to the first embodiment, the paste 75 covering one of the two interlayer connection conductors 32 corresponds to the external electrode 51 among the external electrodes 50, and the paste 75 covering the other of the two interlayer connection conductors 32 corresponds to the external electrode 52 among the external electrodes 50.

(Laminating Step)

Next, a laminating step is performed. In the laminating step, as illustrated in FIG. 8, each of the base materials 21 to 27 excluding the carrier film 71 is laminated in the thickness direction and pressure-bonded in a mold. As a result, the element body 20 is obtained.

In the laminating step, the seven base materials 21 to 27 are laminated in an ascending order of a numerical value thereof, specifically, in the order of the base materials 21, 22, 23, 24, 25, 26, and 27. Consequently, the main surface 21A of the base material 21 and the main surface of the base material 27 become outer surfaces of the element body 20. In other words, the main surface 21A of the base material 21 serves as the main surface 20A of the element body 20, and the main surface of the base material 27 serves as the main surface 20B of the element body 20. Note that although in FIG. 8, the base materials are laminated such that openings of the recesses 73A face an upper side of a page of FIG. 8, laminating each of the base materials 21 to 27 in the opposite direction in the thickness direction also enables lamination such that the openings of the recesses 73A face a lower side of the page of FIG. 8.

In the laminating step, the external electrode 50 enters the base material 21 as a result of pressure-bonding of each of the base materials 21 to 27.

In the laminating step, by laminating each of the base materials 21 to 27, at least a part of the plurality of interlayer connection conductors 31 overlaps each other and is electrically connected to each other when viewed from the thickness direction.

In the method for manufacturing the electronic component 10 according to the first embodiment, by laminating each of the base materials 21 to 27, one interlayer connection conductor 32 formed in the base material 21 and electrically connected to the external electrode 51 and four interlayer connection conductors 31 formed in the base materials 22 to 25 are continuously arranged in the thickness direction. In one interlayer connection conductor 32 and four interlayer connection conductors 31, at least parts of two adjacent interlayer connection conductors overlap each other when viewed from the thickness direction. As a result, the one interlayer connection conductor 32 and the four interlayer connection conductors 31 are electrically connected to each other. Each of the four interlayer connection conductors 31 corresponds to the interlayer connection conductor 311.

In the method for manufacturing the electronic component 10 according to the first embodiment, by laminating each of the base materials 21 to 27, one interlayer connection conductor 32 formed in the base material 21 and electrically connected to the external electrode 52, and one interlayer connection conductor 31 formed in the base material 22 are continuously arranged in the thickness direction. At least parts of one interlayer connection conductor 32 and one interlayer connection conductor 31 overlap each other when viewed from the thickness direction. As a result, the one interlayer connection conductor 32 and the one interlayer connection conductor 31 are electrically connected to each other. One interlayer connection conductor 31 corresponds to the interlayer connection conductor 312.

In the method for manufacturing the electronic component 10 according to the first embodiment, by laminating each of the base materials 21 to 27, three interlayer connection conductors 31 formed respectively in the base materials 24 to 26 are continuously arranged in the thickness direction. In the three interlayer connection conductors 31, at least parts of two adjacent interlayer connection conductors 31 overlap each other when viewed from the thickness direction. As a result, the three interlayer connection conductors 31 are electrically connected to each other. Each of the three interlayer connection conductors 31 corresponds to the interlayer connection conductor 313.

In the laminating step, by laminating each of the base materials 21 to 27, the opening of the recess 73A of each interlayer connection conductor 31 is covered with at least one of the laminated base materials, the internal electrode 40 on the base material, and the interlayer connection conductor 30 formed in the base material. As a result, a space formed by the recess 73A is sealed to form the cavity 31A.

In the method for manufacturing the electronic component 10 according to the first embodiment, by laminating, for example, the base material 24 on the base material 23, the opening of the recess 73A of the interlayer connection conductor 31 formed in the base material 23 is covered with the interlayer connection conductor 31 formed in the laminated base material 24. Furthermore, for example, by laminating the base material 27 on the base material 26, the opening of the recess 73A of the interlayer connection conductor 31 formed in the base material 26 is covered with the laminated base material 27 (in detail, the internal electrode 44 formed on the main surface 27A of the base material 27). The same applies to the recess 73A of the other interlayer connection conductors 31.

When each of the base materials 21 to 27 is laminated, pressure-bonded, or the like in the laminating step, the base material covering the recess 73A, the internal electrode 40, or the like may enter the recess 73A, or the recess 73A may be deformed due to deformation or the like of the interlayer connection conductor 31 in some cases. As a result, a shape and a size of the formed cavity 31A can be different from those of the recess 73A. This can also bring division of one recess 73A to form a plurality of cavities 31A. Furthermore, this can cause the base material or the like to enter the recess 73A, so that the cavity 31A might not be formed.

In the laminating step, by laminating each of the base materials 21 to 27, at least parts of the interlayer connection conductor 31 and the internal electrode 40 overlap each other when viewed from the thickness direction, and at least one insulating layer is interposed between the interlayer connection conductor 31 and the internal electrode 40.

In the method for manufacturing the electronic component 10 according to the first embodiment, by laminating the base materials 25 to 27, the entire interlayer connection conductor 311 formed in the base material 25 and a part of the internal electrode 44 formed on the main surface 27A of the base material 27 overlap each other when viewed from the thickness direction. In addition, the base material 26 is interposed between the interlayer connection conductor 311 formed in the base material 25 and the internal electrode 44 formed on the main surface 27A of the base material 27.

In the method for manufacturing the electronic component 10 according to the first embodiment, by laminating the base materials 22 to 24, the entire interlayer connection conductor 312 formed in the base material 22 and a part of the internal electrode 42 formed on the main surface 24A of the base material 24 overlap each other when viewed from the thickness direction. In addition, the base material 23 is interposed between the interlayer connection conductor 312 formed in the base material 22 and the internal electrode 42 formed on the main surface 24A of the base material 24.

In the method for manufacturing the electronic component 10 according to the first embodiment, by laminating the base materials 23 and 24, the entire interlayer connection conductor 313 formed in the base material 24 and a part of the internal electrode 41 formed on the main surface 23A of the base material 23 overlap each other when viewed from the thickness direction. In addition, the base material 23 is interposed between the interlayer connection conductor 313 formed in the base material 24 and the internal electrode 41 formed on the main surface 23A of the base material 23.

As described above, in the method for manufacturing the electronic component 10 according to the first embodiment, the entire interlayer connection conductor 31 and a part of the internal electrode 40 overlap each other when viewed from the thickness direction. However, a part of the interlayer connection conductor 31 and the entire internal electrode 40 may overlap each other when viewed from the thickness direction, the entire interlayer connection conductor 31 and the entire internal electrode 40 may overlap each other when viewed from the thickness direction, or a part of the interlayer connection conductor 31 and a part of the internal electrode 40 may overlap each other when viewed from the thickness direction.

As described above, in the method for manufacturing the electronic component 10 according to the first embodiment, one layer of the base material is interposed between the entire interlayer connection conductor 31 and a part of the internal electrode 40. However, a plurality of layers of base materials may be interposed between the entire interlayer connection conductor 31 and a part of the internal electrode 40.

(Segmenting Step)

Next, a segmenting step is performed. In the segmenting step, the laminate in which the plurality of element bodies 20 are arrayed is cut into the plurality of element bodies 20. For cutting the laminate, for example, a dicing saw, a guillotine cutter, a laser, or the like is used. After the laminate is cut, a corner and an edge of the element body 20 may be polished by, for example, barrel processing or the like. The polishing may be performed after a firing step.

(Firing Step)

Next, the firing step is performed. In the firing step, the element body 20 is fired. As a result, each of the base materials 21 to 27 constituting the element body 20 is cured. In other words, each of the base materials 21 to 27, which are flexible green sheets, is cured and changed into a substrate.

(Plating Layer Laminating Step)

Next, a plating layer laminating step is performed. In the plating layer laminating step, as shown in FIG. 2, the external electrodes 51 and 52 are subjected to a known plating treatment. As a result, the plating layer 60 is laminated so as to cover the external electrodes 51, 52.

According to this manufacturing method, in the interlayer connection conductor forming step, the recess 73A is formed in the interlayer connection conductor 31. As a result, in the subsequent laminating step or the like, by an amount of deformation of the interlayer connection conductor 31 when the interlayer connection conductor 31 is deformed, an electrode formed in another base material laminated on the interlayer connection conductor 31, and the like can be made to enter the recess 73A. This makes it possible to suppress protrusion of the interlayer connection conductor 31 from the base material.

When the recess 73A is eliminated due to the deformation of the recess 73A or the like in the laminating step, the electrode formed in the other base material laminated on the interlayer connection conductor 31, and the like cannot enter the recess 73A by an amount of the deformation of the interlayer connection conductor 31. This might cause the interlayer connection conductor 31 to protrude from the base material. According to this manufacturing method, a space formed by the recess 73A is not completely eliminated, and the cavity 31A is formed by the remaining space. This makes it possible to suppress protrusion of the interlayer connection conductor 31 from the base material.

According to this manufacturing method, a diameter on the one end side in the thickness direction of the through hole 20D is larger than a diameter on the other end side in the thickness direction of the through hole 20D, and the recess 73A of the interlayer connection conductor 31 is formed on the end surface 73B on the one end side in the thickness direction of the through hole 20D, i.e., the end surface on the side having the larger diameter. This enables the recess 73A formed in the interlayer connection conductor 31 to be enlarged. As a result, when the interlayer connection conductor 31 is deformed, by a larger amount of deformation of the interlayer connection conductor 31, an electrode formed on the other base material, and the like can be made to enter the recess 73A.

According to this manufacturing method, the interlayer connection conductor 31 can be continuously formed in the thickness direction in the laminating step.

### Second Embodiment

FIG. 9 is a cross-sectional view of a part corresponding to the section taken along line A-A in FIG. 1 in an electronic component according to a second embodiment of the present disclosure. An electronic component 10A according to the second embodiment is different from the electronic component 10 according to the first embodiment in that a through hole 20E has a diameter that decreases from the other end (an end on the main surface 20A side) toward one end (an end on the main surface 20B side) in the thickness direction, and the electronic component further includes an internal electrode 45 interposed between two interlayer connection conductors 80 to electrically connect the two interlayer connection conductors 80. In the following, differences from the first embodiment will be described. Common points to the electronic component 10 according to the first embodiment are denoted by the same reference signs, and description thereof will be omitted in principle and will be described as necessary.

As shown in FIG. 9, the electronic component 10A according to the second embodiment includes an element body 90, the interlayer connection conductor 80, the internal electrode 40, the external electrode 50, and the plating layer 60. The external electrode 50 and the plating layer 60 are configured in the same manner as in the electronic component 10 according to the first embodiment.

A shape of the through hole 20E of the element body 90 is opposite to that of the through hole 20D (see FIG. 2) of the element body 20 in the thickness direction. For the remainder, the element body 90 has the same configuration as the element body 20.

The through hole 20E has a diameter that decreases from the main surface 20A toward the main surface 20B along the thickness direction. Specifically, the through hole 20E has a tapered shape having a diameter that decreases from the other end (the end on the main surface 20A side) toward the one end (the end on the main surface 20B side) in the thickness direction.

Although having a truncated cone shape similarly to the interlayer connection conductor 30 (see FIG. 2), the interlayer connection conductor 80 faces opposite to the interlayer connection conductor 30 in the thickness direction. In other words, while the interlayer connection conductor 30 has a diameter that decreases toward the main surface 20A, the interlayer connection conductor 80 has a diameter that increases toward the main surface 20A. Note that in the interlayer connection conductor 80, a positional relationship between a part having a small diameter and a part having a large diameter may be converse to that in FIG. 9. In other words, in FIG. 9, while the interlayer connection conductor 80 has a diameter that decreases toward an upper side of a page, contrary thereto, the interlayer connection conductor 80 may be configured to have a diameter that decreases toward a lower side of the page. Such a configuration can be realized, for example, by reversing a lamination order of the base materials 21 to 27.

The interlayer connection conductor 80 includes eight interlayer connection conductors 81 and two interlayer connection conductors 82. In the second embodiment, the interlayer connection conductor 81 corresponds to the first conductor. The interlayer connection conductor 81 corresponds to the interlayer connection conductor 31 of the electronic component 10 according to the first embodiment, and has the same configuration as the interlayer connection conductor 31 and is provided at the same position. The interlayer connection conductor 82 corresponds to the interlayer connection conductor 32 of the electronic component 10 according to the first embodiment, and has the same configuration as the interlayer connection conductor 32 and is provided at the same position.

The interlayer connection conductor 81 has a cavity 81A. The cavity 81A corresponds to the cavity 31A of the electronic component 10 according to the first embodiment, and has the same configuration as the cavity 31A and is provided at the same position. In the second embodiment, the cavity 81A forms a sealed space.

In a third embodiment, the cavity 81A of each interlayer connection conductor 81 is formed so as to be shifted to the main surface 20A side in the thickness direction, contrary to the cavity 31A of the electronic component 10 according to the first embodiment. In other words, the cavity 81A of each interlayer connection conductor 81 is formed so as to be shifted to the other end side in the thickness direction of the through hole 20E (the side where the through hole 20E has a large diameter).

The internal electrode 40 includes the internal electrode 45 in addition to the internal electrodes 41 to 44 (see FIG. 2). The internal electrode 45 is an example of the third conductor. The internal electrode 45 is formed in at least one of the base materials 21 to 27 in the same manner as the other internal electrodes 41 to 44. In the second embodiment, the internal electrode 45 is formed on the main surface of the base material 22 to 26. In detail, two internal electrodes 45 are formed on main surfaces 22A and 25A of the base materials 22 and 25, respectively, and one internal electrode 45 is formed on main surfaces 23A, 24A, and 26A of the base materials 23, 24, 26, respectively.

The internal electrode 45 is interposed between two interlayer connection conductors 80 each provided in two adjacent base materials and arranged in the thickness direction. The internal electrode 45 is in contact with each of the two interlayer connection conductors 80. In other words, the internal electrode 45 electrically connects the two interlayer connection conductors 80.

According to the second embodiment, the internal electrode 45 is interposed between the two interlayer connection conductors 80. Therefore, an electrical connection between the two interlayer connection conductors 80 can be strengthened.

### Method for Manufacturing Electronic Component According to Second Embodiment

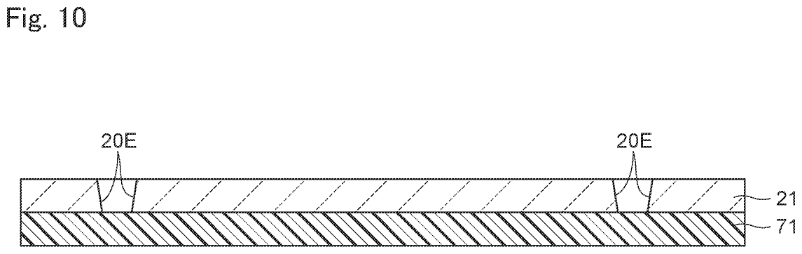

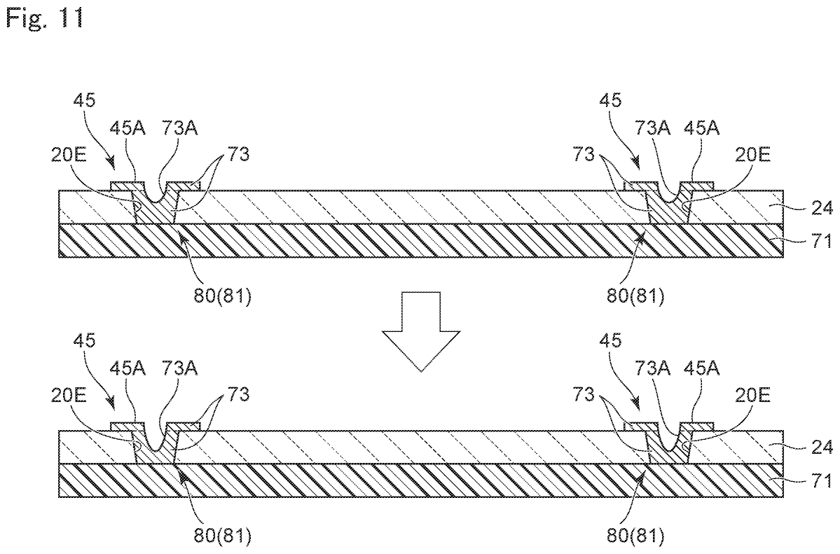

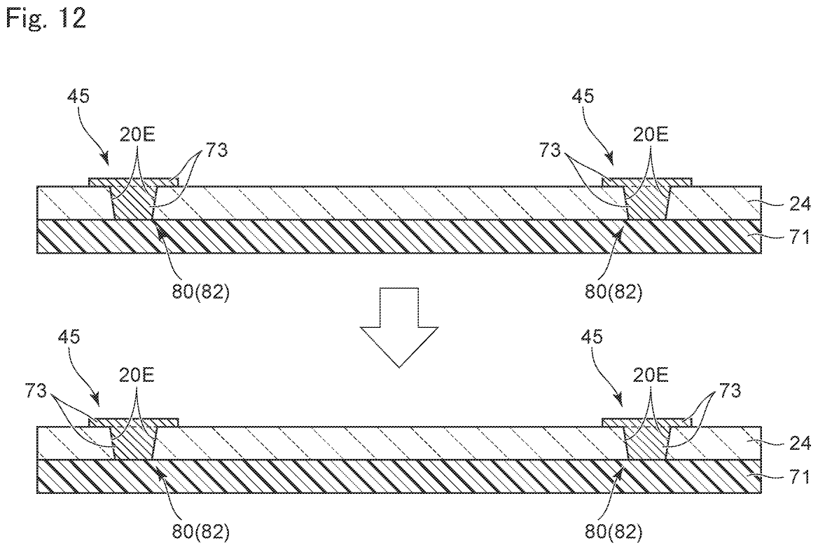

In the following, the method for manufacturing the electronic component 10A according to the second embodiment will be described with reference to FIGS. 10 to 12. FIG. 10 is a cross-sectional view when the through hole is formed in the base material in the method for manufacturing an electronic component according to the second embodiment of the present disclosure. FIG. 11 is a cross-sectional view when the interlayer connection conductor is formed in the through hole of the base material in FIG. 10. FIG. 12 is a cross-sectional view when the interlayer connection conductor is formed in the through hole of the base material in FIG. 10. In the following, differences from the method for manufacturing the electronic component 10 according to the first embodiment will be described. Common points to the method for manufacturing the electronic component 10 according to the first embodiment are denoted by the same reference signs, and description thereof will be omitted in principle and will be described as necessary.

In the method for manufacturing the electronic component 10A according to the second embodiment, the sheet molding step, the through hole forming step, the interlayer connection conductor forming step, the internal electrode forming step, the external electrode forming step, the laminating step, the segmenting step, the firing step, and the plating layer laminating step are performed similarly to the method for manufacturing the electronic component 10 according to the first embodiment.

First, the sheet molding step is performed. The sheet molding step is similar to that of the method for manufacturing the electronic component 10 according to the first embodiment.

Next, a through hole forming step is performed. In the through hole forming step, as illustrated in FIG. 10, the through hole 20E penetrating through each of the base materials 21 to 27 in the thickness direction is formed. In FIG. 10, the carrier film 71 and the base material 21 molded on the carrier film 71 are shown. Unlike the through hole 20D in the method for manufacturing the electronic component 10 according to the first embodiment, the through hole 20E is not formed in the carrier film 71. For example, when the through hole 20E is formed by a laser, while the through hole 20E is formed in ceramic or the like constituting the base material 21, a wavelength of a laser is adjusted such that the through hole 20E is not formed in a PET film or the like constituting the carrier film 71.

Next, an interlayer connection conductor forming step is performed. In the method for manufacturing the electronic component 10A according to the second embodiment, the paste 73 is filled from the base material side (the side opposite to the carrier film 71). In other words, a filling inlet in the method for manufacturing the electronic component 10A according to the second embodiment is reverse to that in the method for manufacturing the electronic component 10 according to the first embodiment.

In the interlayer connection conductor forming step, as illustrated in FIGS. 11 and 12, the conductive paste 73 is filled in each of the through holes 20E formed in each of the base materials 21 to 26 in the through hole forming step. At this time, the paste 73 is formed not only inside the through hole 20E but also in the through hole 20E on the main surface of the base material and surroundings thereof. The paste 73 is formed by, for example, printing from a surface of the base material 24 with a screen plate. The interlayer connection conductor 80 is formed by the paste 73 formed inside the through hole 20E. The internal electrode 45 is formed by the paste 73 formed in the through hole 20E on the main surface of the base material and the surroundings thereof. In this case, the interlayer connection conductor forming step corresponds to the first conductor forming step and also corresponds to the third conductor forming step.

In the interlayer connection conductor forming step, similarly to the method for manufacturing the electronic component 10 according to the first embodiment, the recess 73A is formed in the paste 73 filling the through hole 20E of the base material 22 to 26, and the recess 73A is not formed in the paste 73 filling the through hole 20E of the base material 21. The interlayer connection conductor 81 is formed by the paste 73 in which the recess 73A is formed. The interlayer connection conductor 82 is formed by the paste 73 in which the recess 73A is not formed. In this case, the internal electrode 45 covers a part of the interlayer connection conductor 81 (a part excluding the recess 73A). The internal electrode 45 covers the entire interlayer connection conductor 82.

When the paste 73 is filled in the through hole 20E of the base material 22 to 26, the recess 73A is formed as illustrated in an upper part of FIG. 11 by adjusting the drying conditions and composition of the paste, and the like described in the first embodiment. In FIG. 11, the base material 24 is illustrated as a representative of the base materials 22 to 26. Thereafter, when the filled paste 73 is dried, the paste 73 shrinks, and the recess 73A becomes deep as illustrated in a lower part of FIG. 11.

When the paste 73 is filled in the through hole 20E of the base material 21, the recess 73A is not formed or barely formed as illustrated in an upper part of FIG. 12 by adjusting the drying conditions and composition of the paste, and the like described in the first embodiment. Thereafter, even when the filled paste 73 is dried, the recess 73A is not formed or barely formed.

Next, an internal electrode forming step is performed. In the internal electrode forming step, the internal electrodes 41 to 44 are formed in the same manner as in the method for manufacturing the electronic component 10 according to the first embodiment. The internal electrode 45 may be formed in the same manner as the internal electrodes 41 to 44 not in the through hole forming step but in the internal electrode forming step. In this case, the internal electrode forming step corresponds to the third conductor forming step.

The internal electrode forming step may be performed in parallel with the interlayer connection conductor forming step. In this case, the internal electrodes 41 to 44 are formed in the same manner as in the formation of the internal electrode 45 in the interlayer connection conductor forming step.

Next, an external electrode forming step is performed. The external electrode forming step is similar to that of the method for manufacturing the electronic component 10 according to the first embodiment. The external electrode forming step may be performed in parallel with the interlayer connection conductor forming step, or may be performed after the interlayer connection conductor forming step and before the internal electrode forming step, or may be performed in parallel with the internal electrode forming step.

Next, a laminating step is performed. In the laminating step, each of the base materials 21 to 27 excluding the carrier film 71 is laminated in the thickness direction and pressure-bonded in a mold. As a result, the element body 90 is obtained. The laminating is performed similarly to that in the method for manufacturing the electronic component 10 according to the first embodiment. In the present manufacturing method, the lamination order of the base materials 21 to 27 is the same as that of the electronic component 10 according to the first embodiment. In this case, as shown in FIG. 9, the interlayer connection conductor 80 is in the opposite direction in the thickness direction to the interlayer connection conductor 30 of the electronic component 10 according to the first embodiment (see FIG. 2). In a case where the lamination order of the base materials 21 to 27 is reverse to that of the electronic component 10 according to the first embodiment, the interlayer connection conductor 80 has the same orientation in the thickness direction as the interlayer connection conductor 30 of the electronic component 10 according to the first embodiment.

In the laminating step of the method for manufacturing the electronic component 10A according to the third embodiment, the interlayer connection conductor 80 formed in another base material overlaps a surface 45A (see FIG. 11) of the internal electrode 45 as a result of lamination of the respective base materials 21 to 27. This makes the internal electrode 45 be interposed between the two adjacent interlayer connection conductors 80. As a result, the internal electrode 45 electrically connects the two adjacent first conductors.

Next, the segmenting step, the firing step, and the plating layer laminating step are performed. These steps are similar to those of the method for manufacturing the electronic component 10 according to the first embodiment. The plating layer laminating step is performed to laminate the plating layers 60, so that the electronic component 10A is completed (see FIG. 9).

According to this manufacturing method, in the laminating step, the plurality of base materials 21 to 27 are laminated such that the internal electrode 45 is interposed between the two interlayer connection conductors 80. Therefore, an electrical connection between the two interlayer connection conductors 80 can be strengthened.

### Third Embodiment

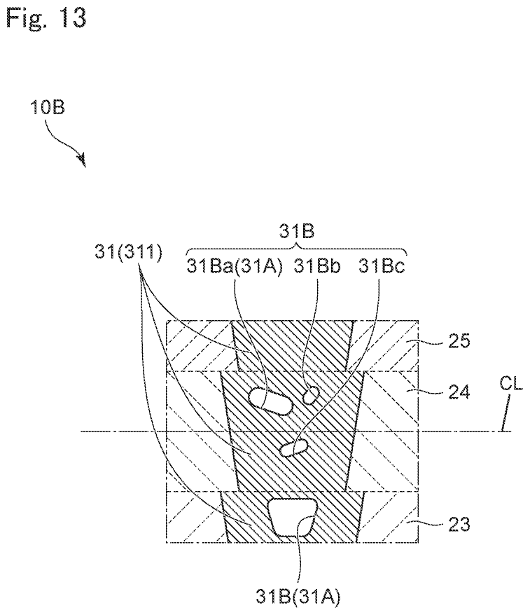

FIG. 13 is an enlarged view of a part corresponding to a part surrounded by a dashed line in FIG. 2 in an electronic component according to the third embodiment of the present disclosure. An electronic component 10B according to the third embodiment is different from the electronic component 10 according to the first embodiment in that the interlayer connection conductor 31 has a plurality of sealed spaces 31B. In the following, differences from the first embodiment will be described. Common points to the electronic component 10 according to the first embodiment are denoted by the same reference signs, and description thereof will be omitted in principle and will be described as necessary.

In the first embodiment, each interlayer connection conductor 31 has one cavity 31A forming one sealed space. In the third embodiment, however, at least one interlayer connection conductor 31 has the plurality of sealed spaces 31B as illustrated in FIG. 13. In FIG. 13, the interlayer connection conductor 31 has three sealed spaces 31Ba, 31Bb, and 31Bc. In this case, the sealed space 31Ba having the largest volume among the plurality of sealed spaces 31B corresponds to the cavity 31A.

Each interlayer connection conductor 31 can have a void forming a sealed space in addition to the sealed spaces 31Ba, 31Bb, and 31Bc as illustrated in FIG. 13. Even in this case, since the volume of the largest sealed space 31Ba among the three sealed spaces 31Ba, 31Bb, and 31Bc is larger than the void, the sealed space 31Ba corresponds to the cavity 31A.

When each interlayer connection conductor 31 has the plurality of sealed spaces 31B, all of the plurality of sealed spaces 31B may correspond to the cavity 31A. In this case, the plurality of sealed spaces 31B of the interlayer connection conductor 31 are formed so as to be shifted to one of the main surface 20B side and the main surface 20A side in the thickness direction of the through hole 20D. For example, in FIG. 13, a total volume of the sealed spaces 31Ba and 31Bb located closer to the main surface 20B side (an upper side of a page of FIG. 13) with respect to a central position CL in the thickness direction of the through hole 20D is larger than a total volume of the sealed space 31Bc located closer to the main surface 20A side (a lower side of the page of FIG. 13) with respect to the central position CL. In this case, the plurality of sealed spaces 31Ba, 31Bb, and 31Bc (in other words, the plurality of cavities 31A) are shifted to the main surface 20B side in the thickness direction of the through hole 20D.

Note that by appropriately combining arbitrary embodiments among the various embodiments described above, the effects of the respective embodiments can be achieved.

Although the present disclosure has been sufficiently described in connection with the preferred embodiments with reference to the drawings as appropriate, various modifications and rectifications are apparent to those skilled in the art. Such modifications and rectifications should be understood to be included within the scope of the present disclosure according to the appended claims without departing therefrom.
10 electronic component
20D through hole
21 base material (insulating layer)
22 base material (insulating layer)
23 base material (insulating layer)
24 base material (insulating layer)
25 base material (insulating layer)
26 base material (insulating layer)
27 base material (insulating layer)
31 interlayer connection conductor (first conductor)
31A cavity
41 internal electrode (second conductor)
42 internal electrode (second conductor)
44 internal electrode (second conductor)
45 internal electrode (third conductor)
73 paste (conductive material)
73A recess

What is claimed is:

1. An electronic component comprising:
a plurality of insulating layers laminated in a thickness direction;
at least one first conductor provided in at least one of the plurality of insulating layers and filled in a through hole penetrating the at least one of the plurality of insulating layers in the thickness direction; and
a second conductor provided at a position where at least a part of the second conductor overlaps the first conductor when viewed from the thickness direction, the second conductor being provided with the at least one insulating layer interposed between the second conductor and the first conductor, wherein
the first conductor has a cavity, wherein
the cavity being provided so as to be shifted to any one of a second conductor side in the thickness direction of the through hole and a side opposite to the second conductor, wherein
the through hole has a tapered shape with a diameter decreasing from one end toward another end in the thickness direction, wherein
the cavity is provided so as to be shifted to one end side in the thickness direction of the through hole, and wherein
the cavity as a whole is located at an inner side of the other end of the through hole when viewed from the thickness direction.

2. The electronic component of claim 1, wherein
the cavity is provided in a central part of the first conductor when viewed from the thickness direction.

3. The electronic component of claim 1, wherein
the at least one first conductor comprises two first conductors, and the plurality of insulating layers comprises two insulating layers,
the two first conductors are provided respectively in the two insulating layers adjacent to each other, and
the two first conductors at least partially overlap each other and are electrically connected to each other when viewed from the thickness direction.

4. The electronic component of claim 3, further comprising:
a third conductor interposed between the two first conductors to electrically connect the two first conductors.

5. The electronic component of claim 1, wherein
a plurality of sealed spaces are provided in the first conductor, and wherein
the cavity forms a sealed space having a largest volume among the plurality of sealed spaces.

6. The electronic component of claim 1, wherein
the first conductor and the second conductor constitute at least a part of an inductor.

7. The electronic component of claim 1, wherein
the first conductor and the second conductor constitute at least a part of a capacitor.

8. A method for manufacturing an electronic component, comprising:
a through hole forming step of forming, in at least one of a plurality of insulating layers, a through hole penetrating the at least one of the plurality of insulating layer in a thickness direction and having a tapered shape with a diameter decreasing from one end toward another end in the thickness direction;
a first conductor forming step of forming at least one first conductor by filling the through hole with a conductive material such that a recess recessed in the thickness direction and located at an inner side of the other end of the through hole when viewed from the thickness direction is formed on an end surface on one end side in the thickness direction of the through hole;
a second conductor forming step of forming a conductive second conductor in at least one of the plurality of insulating layers; and
a laminating step of laminating the plurality of insulating layers in the thickness direction such that at least a part of the first conductor and a part of the second conductor overlap each other when viewed from the thickness direction, and at least one of the insulating layers is interposed between the first conductor and the second conductor.

9. The method for manufacturing an electronic component of claim 8, wherein
in the laminating step, the plurality of insulating layers are laminated such that an opening of the recess is covered with at least one of the laminated insulating layers, the first conductor, and the second conductor to hermetically seal a space formed by the recess to form a cavity.

10. The method for manufacturing an electronic component of claim 8, wherein
in the through hole formation step, the through hole is formed in the plurality of insulating layers, wherein
in the first conductor forming step, the first conductor is formed in the through hole, and wherein
in the laminating step, the plurality of insulating layers are laminated in the thickness direction such that at least a part of the plurality of first conductors overlap and are electrically connected to each other when viewed from the thickness direction.

11. The method for manufacturing an electronic component of claim 10, further comprising:
a third conductor forming step of forming a third conductor on a main surface of at least one of the plurality of insulating layers so as to cover at least a part of the first conductor, and wherein
the at least one first conductor comprises two adjacent first conductors,
in the laminating step, the plurality of insulating layers are laminated in the thickness direction such that the third conductor is interposed between the two adjacent first conductors to electrically connect the two adjacent first conductors.

12. The electronic component of claim 2, wherein
the at least one first conductor comprises two first conductors, and the plurality of insulating layers comprises two insulating layers,
the two first conductors are provided respectively in the two insulating layers adjacent to each other, and
the two first conductors at least partially overlap each other and are electrically connected to each other when viewed from the thickness direction.

13. The electronic component of claim 2, wherein
a plurality of sealed spaces are provided in the first conductor, and wherein
the cavity forms a sealed space having a largest volume among the plurality of sealed spaces.

14. The electronic component of claim 3, wherein
a plurality of sealed spaces are provided in the first conductor, and wherein
the cavity forms a sealed space having a largest volume among the plurality of sealed spaces.

15. The electronic component of claim 4, wherein
a plurality of sealed spaces are provided in the first conductor, and wherein
the cavity forms a sealed space having a largest volume among the plurality of sealed spaces.

16. The electronic component of claim 2, wherein
the first conductor and the second conductor constitute at least a part of an inductor.

17. The electronic component of claim 3, wherein
the first conductor and the second conductor constitute at least a part of an inductor.

18. The electronic component of claim 4, wherein
the first conductor and the second conductor constitute at least a part of an inductor.

19. The electronic component of claim 5, wherein
the first conductor and the second conductor constitute at least a part of an inductor.

20. The electronic component of claim 2, wherein
the first conductor and the second conductor constitute at least a part of a capacitor.
